(19) United States
(12) Patent Application Publication
(10) Pub. No.: US 2007/0063201 A1
(43) Pub. Date: Mar. 22, 2007

(54) OPTICAL MODULE HAVING A LENS FORMED WITHOUT CONTACTING A REFLECTOR AND METHOD OF MAKING THE SAME

(76) Inventor: Cheng-Chung Kuo, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/306,636

(22) Filed: Jan. 5, 2006

(30) Foreign Application Priority Data
Sep. 22, 2005 (TW) 094132902

(51) Int. Cl. H01L 21/00

(52) U.S. Cl. 257/79; 438/22

(57) ABSTRACT

An optical module includes a substrate, a chip, a reflector and a lens. The chip is disposed on the substrate for emitting light. The reflector is disposed on the substrate for reflecting light emitted by the chip. The lens is formed on the substrate using resin. The lens covers the chip and is not in contact with the reflector.

### BACKGROUND OF THE INVENTION

1. Field of the Invention

The present invention is related to an optical module and a method of making the same, and more particularly, to an optical module having a lens formed without contacting a reflector and a method of making the same.

2. Description of the Prior Art

Optical modules which generate light using light-emitting components have be applied to various products, such as laser pointers, display panels of cellular phones, television remote controls, or flash light source of photo cellular phones. Please refer to FIG. 1 of a diagram illustrating a conventional optical module 10. The optical module 10 includes a substrate 12, a chip 14, a reflector 16, and a lens 18. The chip 14, usually using light-emitting components such as light emitting diodes (LEDs) or laser diodes (LDs), is disposed on the substrate 12. The reflector 16 is disposed on the substrate 12 and surrounds the chip 14. A circular surface 17 of the reflector 16 is disposed at a certain angle with respect to the substrate 12 for reflecting light emitted by the chip 14. The lens 18, formed on the substrate 12 and within the reflector 16, covers the chip 14 and is in contact with the circular surface 17 of the reflector 16. The thickness of the lens 18 is equal to the height of the reflector 16. In the optical module 10, part of the light emitted by chip 14 is refracted directly by the lens 18, and part of the light emitted by chip 14 is refracted by the lens 18 after being reflected by the circular surface 17 of the reflector 16. The optical module 10 has two perceivable drawbacks:

(1) The intensity of light decreases with the traveling distance after it has been emitted from the light source. In the optical module 10, the light emitted by the chip 14 travels a long distance within the lens 18 before being refracted by the lens 18, especially the part of the light that is reflected by the circular surface 17 of the reflector 16 and then refracted by the lens 18. Therefore, the optical module 10 has low light intensity.

(2) In the optical module 10, the refracting surface of the lens 18 has large area, thus providing a wide emitting angle for the refracted light. At a certain distance from the refracting surface of the lens 18, the refracted light generates a large illuminated area and the effective light intensity per unit area is relatively small. Therefore, the optical module 10 provides low effective light intensity per unit area.

Please refer to FIG. 2 of a diagram illustrating another conventional optical module 20. Compared to the optical module 10, the optical module 20 further includes an extra lens 28. The extra lens 28 can converge the refracted light of the lens 18 and reduces the emitting angle of the refracted light. Therefore, the optical module 20 provides larger effective light intensity per unit area and can solve the problem mentioned in drawback (2). However, the light emitted by the chip 14 has to travel through the lens 18 and the extra lens 28 in the optical module 20. Therefore, the extra lens 28, though capable of converging the reflected light of the lens 18, increases the travel distance of light and reduces the light intensity provided by the optical module 20. Also, the extra lens 28 occupies large space and adds to manufacturing costs of the optical module 20.

Please refer to FIG. 3 of a diagram illustrating another conventional optical module 30. The optical module 30 includes the substrate 12, the chip 14, the reflector 16, and a lens 38. The lens 38, also formed on the substrate 12 and within the reflector 16, covers the chip 14 and is in contact with the circular surface 17 of the reflector 16. The lens 38 differs from the lens 18 in that the thickness of the lens 38 is smaller than that of the lens 18 for reducing the travel distance of light. The optical module 30 can solve the problem mentioned in drawback (1). However, the refracting surface of the lens 38 still has large area and suffers from low effective light intensity per unit area mentioned in drawback (2).

The prior art optical module 10 provides low light intensity and low effective light intensity per unit area. The prior art optical module 20 improves the effective light intensity per unit area by adding the extra lens 28, but at the same time lowers the light intensity and raises manufacturing cost. The prior art optical module 30 improves the light intensity by using the lens 38 of smaller thickness, but at the same time lowers the effective light intensity per unit area.

### SUMMARY OF THE INVENTION

It is therefore a prime objective of the present invention to provide an optical module and a method of making the same in order to solve the problems of the prior art.

The claimed invention provides an optical module comprising a substrate, a chip disposed on the substrate for emitting light, a reflector disposed on the substrate for reflecting the light emitted by the chip, and a first lens comprising resin, disposed on the substrate, covering the chip and without contacting the reflector.

The claimed invention provides a method for making an optical module comprising: (a) providing a substrate; (b) disposing a chip on the substrate; (c) disposing a reflector on the substrate; and (d) forming a first lens on the substrate using resin, wherein the first lens covers the chip and is not in contact with the reflector.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a prior art optical module.

FIG. 2 is a diagram of another prior art optical module.

FIG. 3 is a diagram of another prior art optical module.

FIG. 4 is a diagram showing a cross-sectional view of an optical module according to the present invention.

FIG. 5 is a diagram showing a top view of the optical module in FIG. 4.

FIG. 6 is a diagram showing a cross-sectional view of an optical module according to a first embodiment of the present invention.

FIG. 7 is a diagram showing a cross-sectional view of an optical module according to a second embodiment of the present invention.

FIG. 8 is a diagram showing a cross-sectional view of an optical module according to a third embodiment of the present invention.

FIG. 9-11 are flowcharts illustrating methods of making optical modules according to the present invention.

FIG. 12-26 are diagrams illustrating methods of making a lens in an optical module according to the present invention.

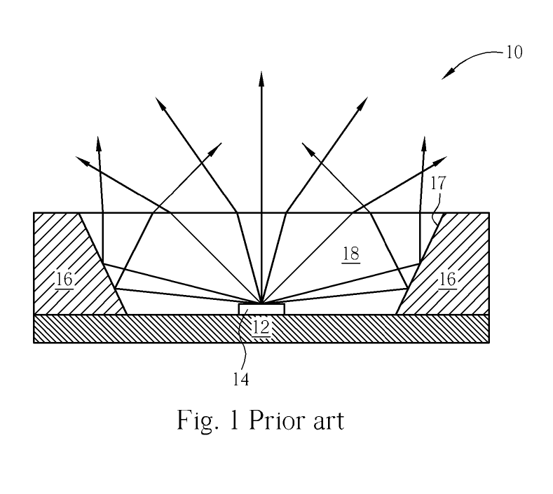

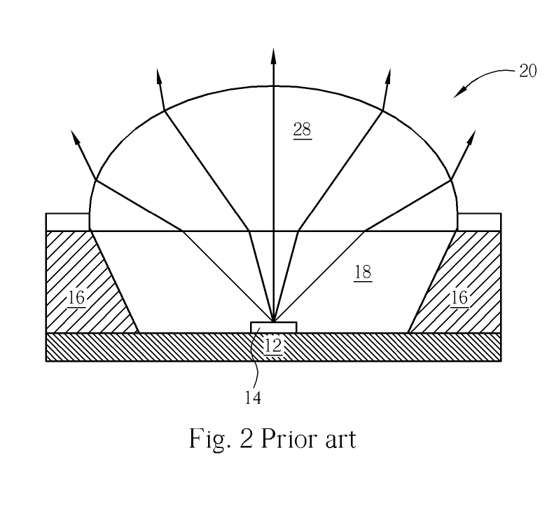

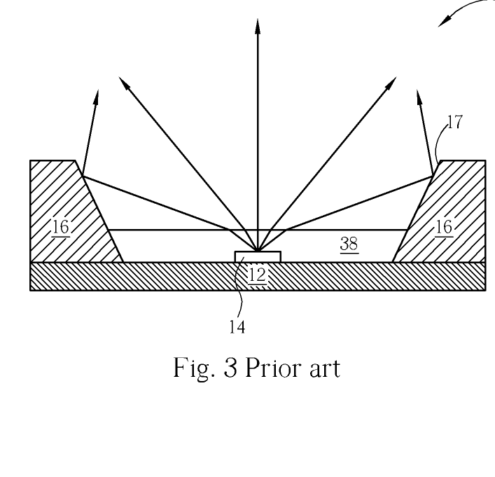

### DETAILED DESCRIPTION

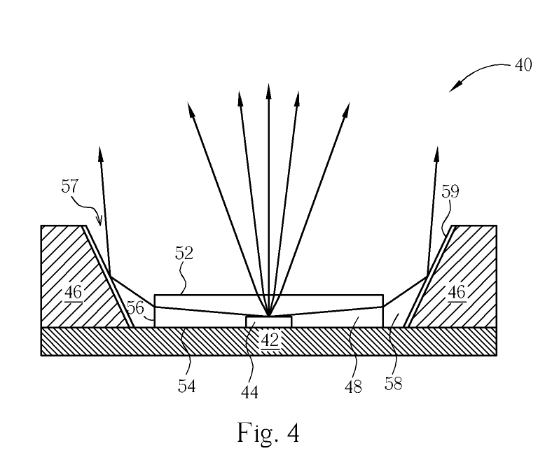

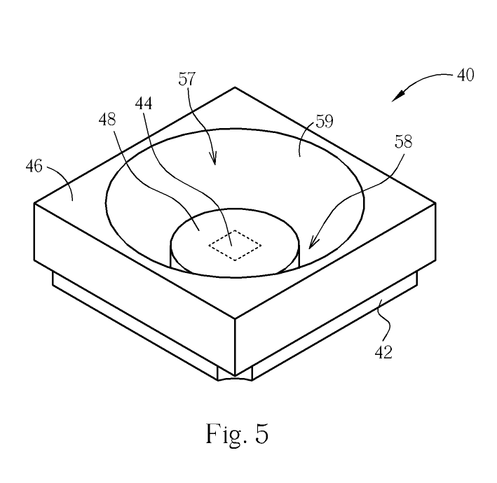

Please refer to FIG. 4 and FIG. 5. FIG. 4 is a diagram showing a cross-sectional view of an optical module 40 according to the present invention. FIG. 5 is a diagram showing a top view of the optical module 40. The optical module 40 includes a substrate 42, a chip 44, a reflector 46 and a first lens 48. The chip 44 is disposed on the substrate 42 and includes light emitting devices such as light emitting diodes or laser diodes.

The reflector 46 includes an upper opening 57, a lower opening 58, and a circular surface 59. The reflector 46 is disposed on the substrate 42. At a contact surface of a bottom of the reflector and the substrate 42, the lower opening 58 defines a region on which the chip 44 is to be disposed. The circular surface 59 of the reflector 46 is disposed between the upper opening 57 and the lower opening 58. In addition, the circular surface 59 is disposed at a certain angle with respect to the substrate 42 for reflecting light emitted by the chip 44. The circular surface 59 of the reflector 46 can be coated with reflective material such as highly reflective aluminum so that the reflector 46 can reflect light more effectively.

The first lens 48 is formed on the substrate 42 using resin and covers the chip 44. The first lens 48 is not in contact with the circular surface 59 of the reflector 46, and the thickness of the first lens 48 is smaller than the height of the reflector 46. In the embodiment shown in FIG. 4, the first lens, with a shape resembling a short cylinder, includes a refracting surface 52 capable of refracting light, a contact surface 54 in contact with the substrate 42, and a flank 56 defining the thickness of the first lens 48. The chip 42 is disposed at a center of the contact surface 54, and the thickness of the first lens 48 is significantly smaller than the height of the reflector 46. The first lens 48 formed by resin can include epoxy or other thermosetting compounds. In addition, for different types of the chip 44, the first lens 48 formed by resin can further include fluorescence material for enhancing the transmittance of light in the first lens 48.

Since in the optical module 40, the thickness of the first lens 48 is significantly smaller than the height of the reflector 46, most of the light emitted by the chip 44 travels through the refracting surface 52 of the first lens 48, and the traveling distance from the chip 44 to the refracting surface 52 is largely reduced. Therefore, the optical module 40 can provide stronger light intensity. Since the first lens 48 is not in contact with the reflector 46, the area of the refracting surface 52 is smaller than that of the refracting surface of the prior art lens 18. Thus, the light refracted by the first lens 48 is limited to a smaller angle. Compared to the prior art optical modules 10, 20, 30, the optical modules 40 of the present invention can provide larger effective light intensity per unit area. Meanwhile, a small portion of light emitted by the chip 44 travels through the flank 56 of the first lens 48 and is reflected by the reflector 46. Since the circular surface 59 of the reflector 46 is coated with reflective material, it can reflect the light refracted by the flank 56 of the first lens 48 more efficiently. The first lens 48 can reduce the travel distance of the light and reduce the emitting angle of the refracted light. Therefore, the optical module 40 of the present invention can provide stronger light intensity and larger effective light intensity per unit area.

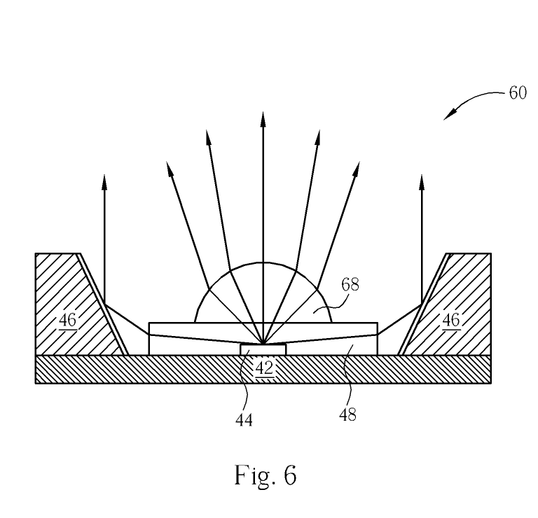

Please refer to FIG. 6 for a diagram showing a cross-sectional view of an optical module 60 according to a first embodiment of the present invention. The optical module 60 differs from the optical module 40 in that the optical module 60 further comprises a second lens 68. The second lens 68 is formed on the first lens 48 using resin, and can be a convex lens. The second lens 68, capable of converging light passing through the first lens 48, further reduces the emitting angle of the refracted light and further improves the effective light intensity per unit area of the optical module 60.

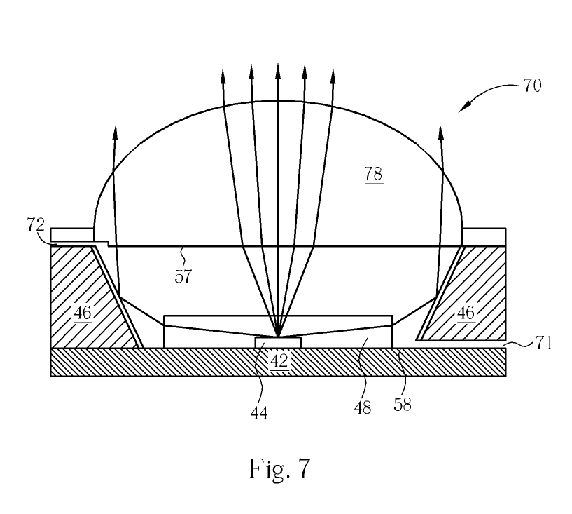

Please refer to FIG. 7 for a diagram showing a cross-sectional view of an optical module 70 according to a second embodiment of the present invention. The optical module 70 differs from the optical module 40 in that the optical module 70 further comprises a third lens 78, vent 71and 72. The third lens 78 is disposed on the reflector 46 for converging light that has been refracted by the first lens 48 and reflected by the reflector 46. The third lens 78 further reduces the emitting angle of the light and further improves the effective light intensity per unit area of the optical module 70. The vent 71 is disposed between the reflector 46 and the substrate 42 and the vent 72 is disposed between the reflector 46 and the third lens 78 for providing a heat dissipation path for the optical module 70. Since in the optical module 70, the reflector 46 is disposed on the substrate 42 and the third lens 78 is disposed on the reflector 46, the lower opening 58 of the reflector 46 is in close contact with the substrate 46 and the upper opening 57 of the reflector 46 is in close contact with the third lens 78. If the optical module 70 does not include vents 71 and 72, the lower opening 58, the upper opening 57 and the substrate 42 form a sealed space, in which the heat generated by the chip 44 when emitting light can not be dissipated easily. For better heat dissipation, the vents 71 and 72 are therefore included in the optical module 70. The optical module 70 can include both the vents 71 and 72 at the same time, the vent 71 solely, the vent 72 solely, or more vents.

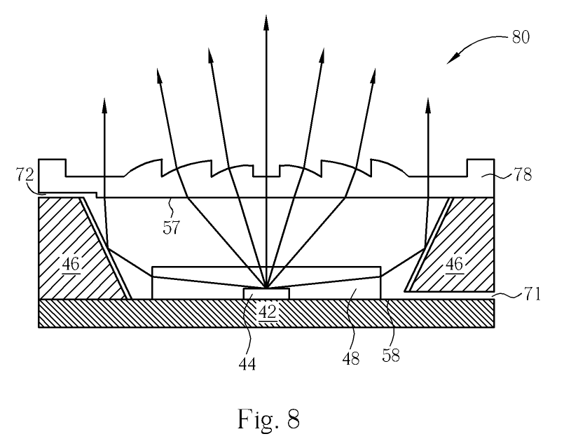

The third lens 78 of the optical lens 70 can include a convex, as shown in FIG. 7. The third lens 78 of the optical lens 70 can also include a fresnel lens, such as an optical module 80 according to a third embodiment of the present invention shown in FIG. 8.

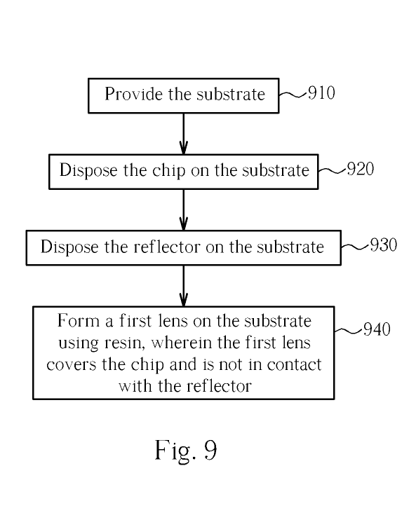

Please refer to FIG. 9 for a flowchart illustrating a method of making optical modules according to the present invention. The flowchart of FIG. 9 can be used for making the optical module 40 and includes the following steps:

Step 910: provide the substrate 42;

Step 920: dispose the chip 44 on the substrate 42;

Step 930: dispose the reflector 46 on the substrate 42; and

Step 940: form a first lens 48 on the substrate 42 using resin, wherein the first lens 48 covers the chip 44 and is not in contact with the reflector 46.

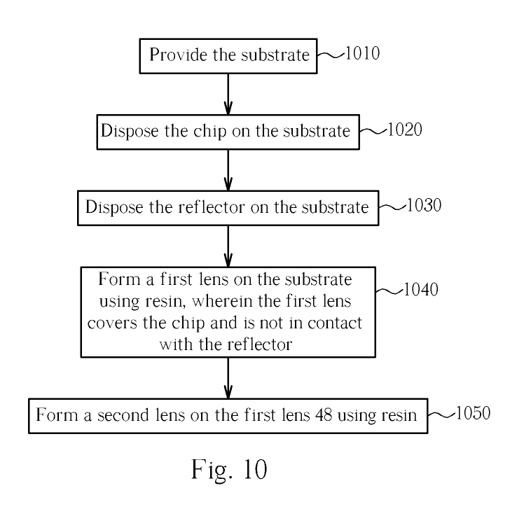

Please refer to FIG. 10 for a flowchart illustrating another method of making optical modules according to the present invention. The flowchart of FIG. 10 can be used for making the optical module 60 and includes the following steps:

Step 1010: provide the substrate 42;

Step 1020: dispose the chip 44 on the substrate 42;

Step 1030: dispose the reflector 46 on the substrate 42;

Step 1040: form a first lens 48 on the substrate 42 using resin, wherein the first lens 48 covers the chip 44 and is not in contact with the reflector 46; and

Step 1050: form a second lens 68 on the first lens 48 using resin.

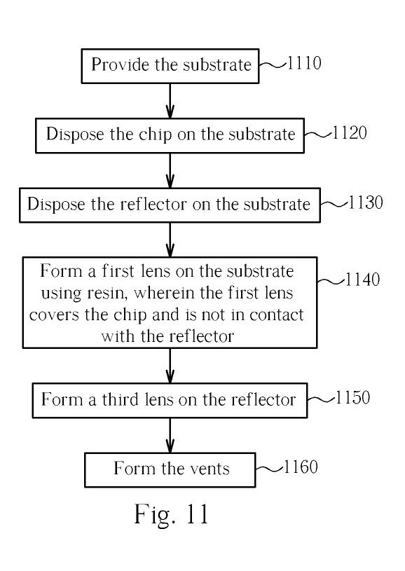

Please refer to FIG. 11 for a flowchart illustrating another method of making optical modules according to the present invention. The flowchart of FIG. 11 can be used for making the optical module 70 and includes the following steps:

Step 1110: provide the substrate 42;

Step 1120: dispose the chip 44 on the substrate 42;

Step 1130: dispose the reflector 46 on the substrate 42;

Step 1140: form a first lens 48 on the substrate 42 using resin, wherein the first lens 48 covers the chip 44 and is not in contact with the reflector 46;

Step 1150: form a third lens 78 on the reflector 46; and

Step 1160: form the vents 71 and 72.

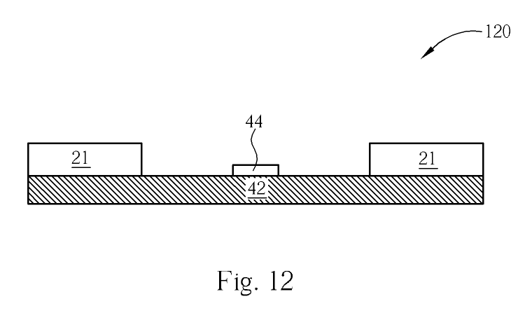

Please refer to FIG. 12-14 illustrating a first method of making the first lens 48 in steps 940, 1040 and 1140. The first method includes the following steps:

Step 120: dispose a stencil 21 on the substrate 42;

Step 130: fill resin into the stencil 12 in a region 25 defining the shape of the first lens 48 using a scraper 23; and

Step 140: remove the stencil 21 and solidify the resin in the region 25 by thermal curing to form the first lens 48.

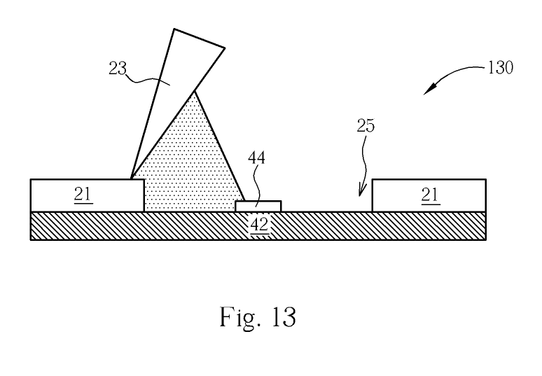

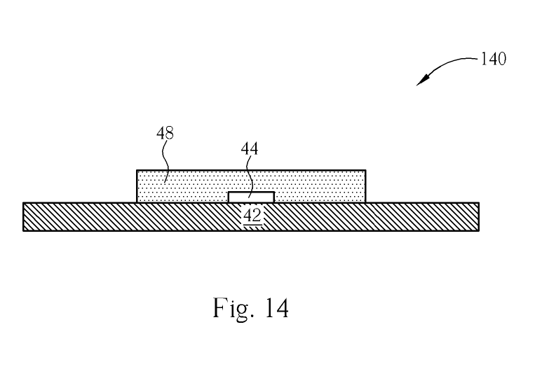

FIG. 12 corresponds to step 120, FIG. 13 corresponds to step 130, and FIG. 14 corresponds to the first lens 48 formed after step 140 in the first method.

Please refer to FIG. 14-16 illustrating a second method of making the first lens 48 in steps 940, 1040 and 1140. The second method includes the following steps:

Step 150: dispose an encapsulate board 31 on the substrate 42;

Step 160: fill resin into the encapsulate board 31 in a region 35 defining the shape of the first lens 48 using a dispenser 33; and

Step 165: remove the encapsulate board 31 and solidify the resin in the region 35 by thermal curing to form the first lens 48.

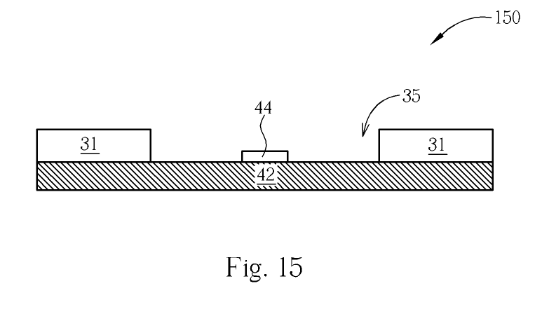

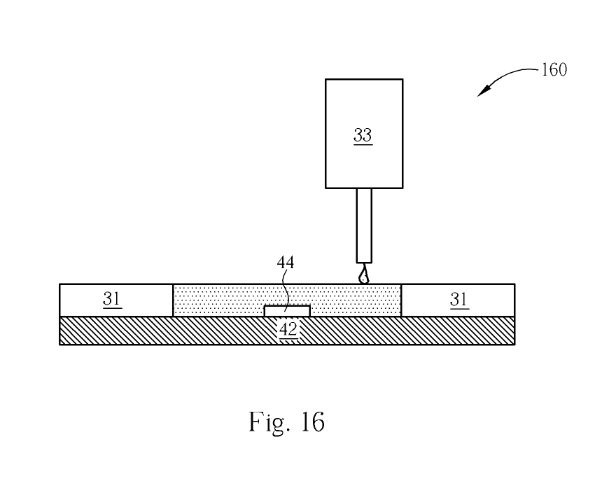

FIG. 15 corresponds to step 150, FIG. 16 corresponds to step 160, and FIG. 14 also corresponds to the first lens 48 formed after step 165 in the second method.

Please refer to FIG. 14, 17-19 illustrating a third method of making the first lens 48 in steps 940, 1040 and 1140. The third method includes the following steps:

Step 170: dispose a mold 41 on the substrate 42;

Step 180: fill resin into the mold 41 in a second region 45 defining the first lens 48 through a first region 43 disposed at a side of the mold 41 for providing an injection path for the resin and in the first region 43;

Step 190: remove the mold 41; and

Step 195: remove resin in the first region 43 and solidify resin in the second region 45 by thermal curing to form the first lens 48.

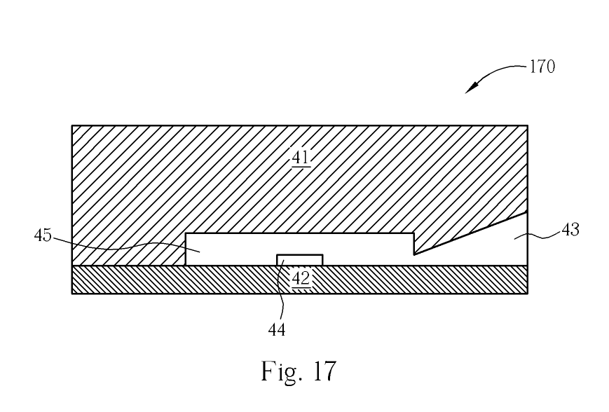

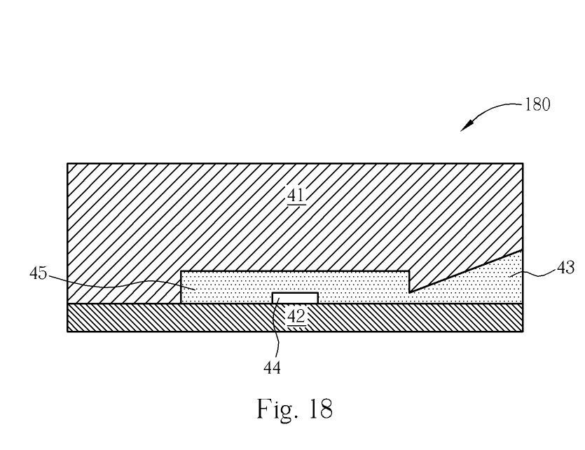

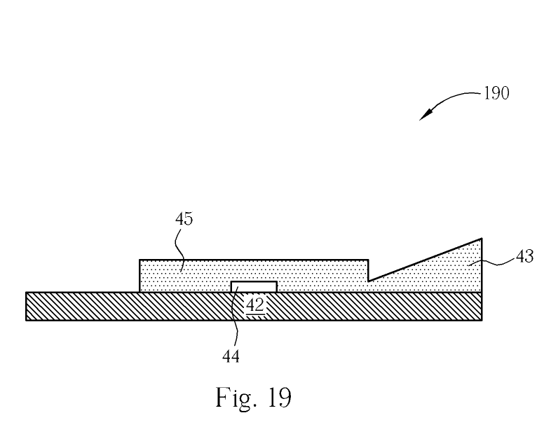

FIG. 17 corresponds to step 170, FIG. 18 corresponds to step 180, FIG. 19 corresponds to step 190, and FIG. 14 also corresponds to the first lens 48 formed after step 195 in the third method.

Please refer to FIG. 14, 20 and 21 illustrating a fourth method of making the first lens 48 in steps 940, 1040 and 1140. The fourth method includes the following steps:

Step 200: dispose a mold 51 on the substrate 42;

Step 210: fill resin into the mold 41 in a second region 55 defining the shape of the first lens 48 through a first region 53 disposed at a top side of the mold 51 for providing an injection path for the resin; and

Step 215: remove the mold 51 and solidify resin in the second region 55 by thermal curing to form the first lens 48.

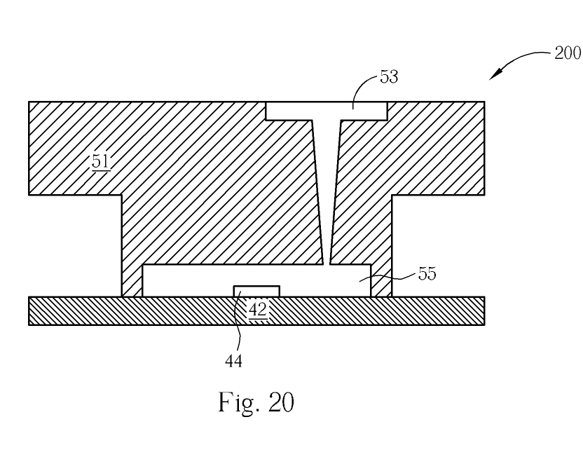

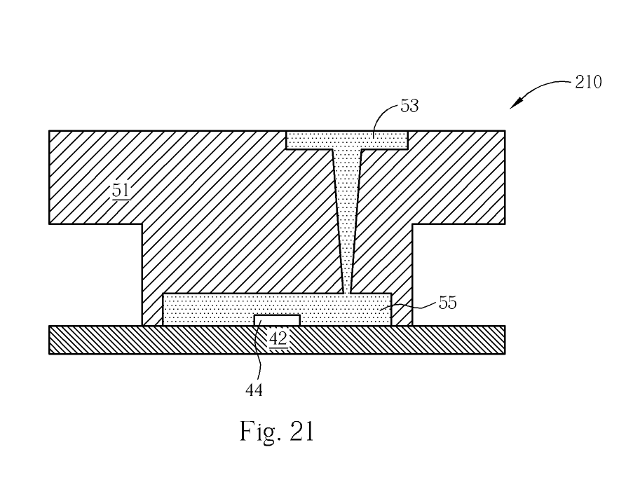

FIG. 20 corresponds to step 200, FIG. 21 corresponds to step 210, and FIG. 14 also corresponds to the first lens 48 formed after step 215 in the fourth method.

Please refer to FIG. 14, 22-24 illustrating a fifth method of making the first lens 48 in steps 940, 1040 and 1140. The fifth method includes the following steps:

Step 220: dispose a tape 63 on the substrate 42 in a region on which the first lens 48 is not to be disposed;

Step 230: dispose a mold 61 on the substrate 42;

Step 240: fill resin into the mold 61 in a second region 67 defining the shape of the first lens 48 through a first region 65 disposed at a side of the mold 61 for providing an injection path for the resin; and

Step 245: remove the mold 61 and the tape 63 and solidify resin in the second region 67 by thermal curing to form the first lens 48.

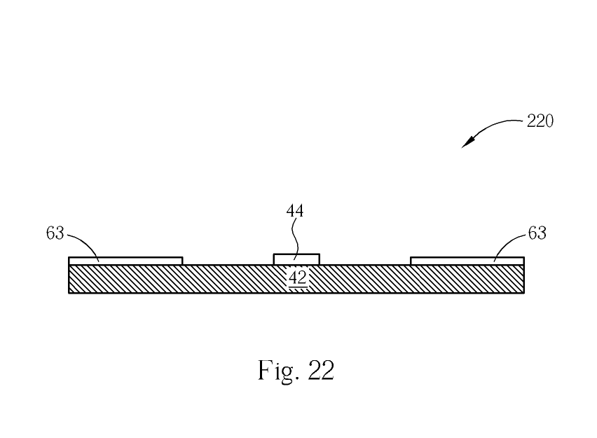

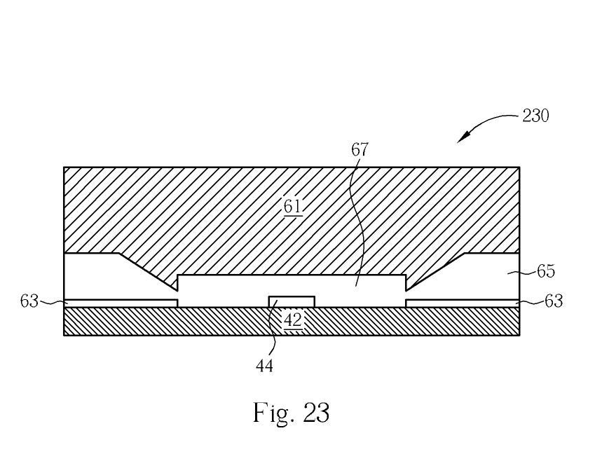

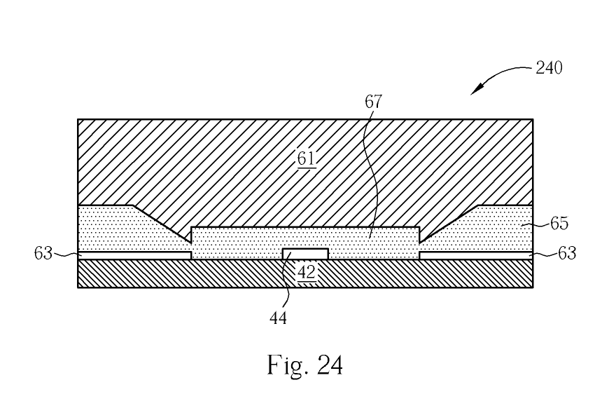

FIG. 22 corresponds to step 220, FIG. 23 corresponds to step 230, FIG. 24 corresponds to step 240, and FIG. 14 also corresponds to the first lens 48 formed after step 245 in the fifth method.

Please refer to FIG. 14, 25 and 26 illustrating a sixth method of making the first lens 48 in steps 940, 1040 and 1140. The sixth method includes the following steps:

Step 250: cover the chip 44 and the substrate 42 with resin using a dispenser 73;

Step 260: remove resin in a region of the substrate 42 on which the first lens 48 is not to be disposed using a miller 75; and

Step 265: solidify the remaining resin by thermal curing to form the first lens 48.

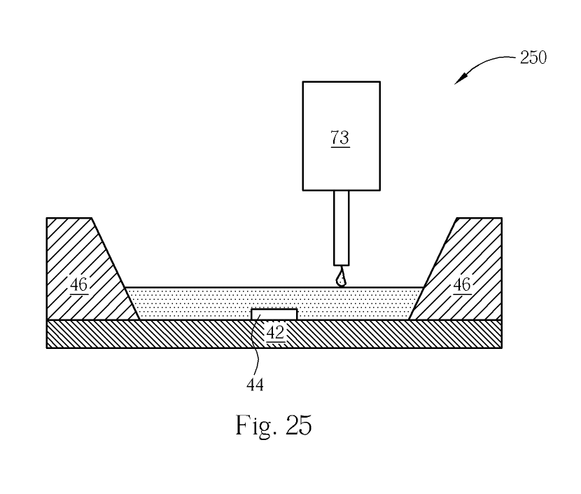

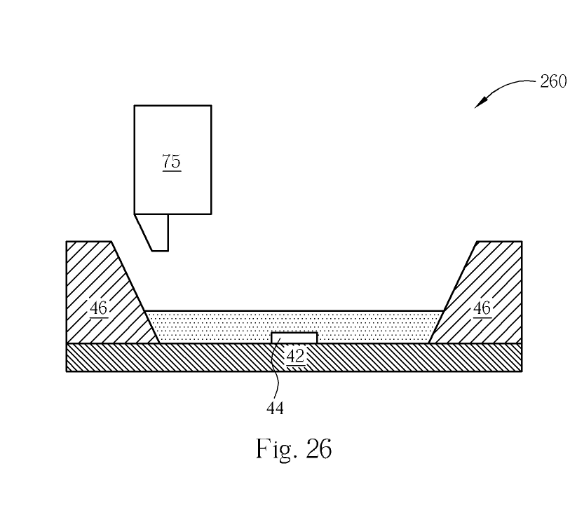

FIG. 25 corresponds to step 250, FIG. 26 corresponds to step 260, and FIG. 14 also corresponds to the first lens 48 formed after step 265 in the sixth method.

The present invention is not limited to the first through sixth methods described above. The present invention includes all methods capable of forming a lens which covers the chip and does not contact the reflector.

In conclusion, the present invention provides an optical module having a lens formed without contacting a reflector and a method of making the same. The optical module in the present invention can reduce the travel distance and the emitting angle of the light. Also, the circular surface of the reflector is coated with reflective material. As a result, the optical module of the present invention can reflect light having been refracted by the flank side of the lens more effectively. Compared to the prior art, the present invention provides optical modules capable of providing stronger light intensity and larger effective light intensity per unit area.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An optical module comprising:
a substrate;
a chip disposed on the substrate for emitting light;
a reflector disposed on the substrate for reflecting the light emitted by the chip; and
a first lens comprising resin, disposed on the substrate covering the chip and without contacting the reflector.

2. The optical module of claim 1 wherein a surface of the reflector is coated with reflective material.

3. The optical module of claim 1 wherein the resin includes epoxy.

4. The optical module of claim 1 wherein the resin includes fluorescence material.

5. The optical module of claim 1 wherein the resin includes thermosetting compound.

6. The optical module of claim 1 wherein the first lens is a planar mirror.

7. The optical module of claim 1 wherein the first lens is a convex mirror.

8. The optical module of claim 1 further comprising a second lens comprising resin and disposed on the first lens for refracting light passing through the first lens.

9. The optical module of claim 8 wherein the first lens is a planar mirror and the second lens is a convex mirror.

10. The optical module of claim 1 further comprising a third lens disposed on the reflector for refracting light emitted by the chip.

11. The optical module of claim 10 further comprising a vent for providing a heat dissipation path for the optical module.

12. The optical module of claim 11 wherein the vent is disposed between the third lens and the reflector.

13. The optical module of claim 11 wherein the vent is disposed between the substrate and the reflector.

14. The optical module of claim 1 wherein the substrate is a printed circuit board (PCB).

15. The optical module of claim 1 wherein the chip is a light emitting diode (LED) or a laser diode (LD).

16. A method for making an optical module comprising the following steps:
(a) providing a substrate;
(b) disposing a chip on the substrate;
(c) disposing a reflector on the substrate; and
(d) forming a first lens on the substrate using resin, wherein the first lens covers the chip and is not in contact with the reflector.

17. The method of claim 16 further comprising:
forming a second lens on the first lens using resin.

18. The method of claim 16 further comprising:
disposing a third lens on the reflector.

19. The method of claim 18 further comprising:
forming a vent between the third lens and the reflector.

20. The method of claim 18 further comprising:
forming a vent between the substrate and the reflector.
